(19) United States
(12) Patent Application Publication
(10) Pub. No.: US 2025/0204150 A1
(43) Pub. Date: Jun. 19, 2025

(54) DISPLAY DEVICE

(71) Applicant: Samsung Display Co., Ltd., Yongin-si (KR)

(72) Inventors: HYEONGSEOK KIM, Yongin-si (KR); HEEJEAN PARK, Yongin-si (KR); SUNHWA LEE, Yongin-si (KR); MUKYUNG JEON, Yongin-si (KR)

(21) Appl. No.: 18/801,086

(22) Filed: Aug. 12, 2024

(30) Foreign Application Priority Data
Dec. 15, 2023 (KR) 10-2023-0182710

(51) Int. Cl. H10K 59/121; G02B 27/01; H10K 59/131; H10K 59/88

(52) U.S. Cl. CPC H10K 59/1213; H10K 59/131; H10K 59/88; G02B 27/0172

(57) ABSTRACT

A display device includes: a light-emitting element; a first transistor including a first semiconductor layer connected to a first power supply line and the light-emitting element, and a first gate electrode on the first semiconductor layer and connected to a first node; a second transistor including a second semiconductor layer connected to the first node and a second node, a (2-1)-th gate electrode on the second semiconductor layer, and a (2-2)-th gate electrode below the second semiconductor layer; a data line connected to the second node; and a third transistor including a third semiconductor layer connected to the second node and the light-emitting element, a (3-1)-th gate electrode on the third semiconductor layer, and a (3-2)-th gate electrode below the third semiconductor layer, wherein the (2-2)-th gate electrode and the (3-2)-th gate electrode are on layers above the first gate electrode, and are on different layers.

### CROSS-REFERENCE TO RELATED APPLICATION

The present application claims priority to and the benefit of Korean Patent Application No. 10-2023-0182710, filed on Dec. 15, 2023, in the Korean Intellectual Property Office, the entire disclosure of which is incorporated herein by reference.

### BACKGROUND

Aspects of some embodiments of the present disclosure herein relate to a display device.

In general, an electronic apparatus, such as a smartphone, a digital camera, a laptop computer, a car navigation unit, and a smart television, which display images to users, includes a display device for displaying images. A display device generates images and provides the generated images to users through a display screen.

A display device includes a display panel including a plurality of pixels for generating images, a scan driver for applying scan signals to the pixels, and a data driver for applying data voltages to the pixels. The pixels receive data voltages in response to the scanning signals and generate images using the data voltages.

Recently, high-resolution display devices have been desired by consumers. Display panels generally include a display region and a non-display region surrounding the display region, and pixels are in the display region. As the number of pixels in the display region increases, the resolution of the display device increases. In order to increase the number of pixels in the display region, it may be desirable to develop a technology for relatively reducing the sizes of pixels.

The above information disclosed in this Background section is only for enhancement of understanding of the background and therefore the information discussed in this Background section does not necessarily constitute prior art.

### SUMMARY

Aspects of some embodiments of the present disclosure include a display device capable of achieving high resolution by relatively reducing the sizes of pixels.

Aspects of some embodiments of the present disclosure include a display device including: a light-emitting element; a first transistor including a first semiconductor layer connected to a first power supply line and the light-emitting element, and a first gate electrode on the first semiconductor layer and connected to a first node; a second transistor including a second semiconductor layer connected to the first node and a second node, a (2-1)-th gate electrode on the second semiconductor layer, and a (2-2)-th gate electrode below the second semiconductor layer; a data line connected to the second node; and a third transistor including a third semiconductor layer connected to the second node and the light-emitting element, a (3-1)-th gate electrode on the third semiconductor layer, and a (3-2)-th gate electrode below the third semiconductor layer, wherein the (2-2)-th gate electrode and the (3-2)-th gate electrode are on layers above the first gate electrode, and are on different layers.

According to some embodiments of the present disclosure, a display device includes: a light-emitting element; a first transistor including a first semiconductor layer connected to a first power supply line and the light-emitting element, and a first gate electrode on the first semiconductor layer and connected to a first node; a second transistor including a second semiconductor layer connected to the first node and a second node, a (2-1)-th gate electrode on the second semiconductor layer, and a (2-2)-th gate electrode below the second semiconductor layer; a data line connected to the second node; and a third transistor including a third semiconductor layer connected to the second node and the light-emitting element, a (3-1)-th gate electrode on the third semiconductor layer, and a (3-2)-th gate electrode below the third semiconductor layer, wherein the (2-2)-th gate electrode and the (3-2)-th gate electrode are on layers above the first gate electrode, and the (2-2)-th gate electrode is on a layer above the (3-2)-th gate electrode.

According to some embodiments of the present disclosure, a display device includes: a light-emitting element; a first transistor including a first semiconductor layer connected to a first power supply line and the light-emitting element, and a first gate electrode on the first semiconductor layer and connected to a first node; an insulating layer on the first transistor; a second transistor including a second semiconductor layer on the insulating layer and connected to the first node and a second node, a (2-1)-th gate electrode on the second semiconductor layer, and a (2-2)-th gate electrode below the second semiconductor layer; a data line connected to the second node; and a third transistor including a third semiconductor layer on the insulating layer and connected to the second node and the light-emitting element, a (3-1)-th gate electrode on the third semiconductor layer, and a (3-2)-th gate electrode below the third semiconductor layer, wherein the (2-2)-th gate electrode and the (3-2)-th gate electrode are on different layers on the insulating layer.

### BRIEF DESCRIPTION OF THE FIGURES

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a perspective view of a display device according to some embodiments of the present disclosure;

FIG. 2 illustrates a cross-sectional view of a display device illustrated in FIG. 1 according to some embodiments of the present disclosure;

FIG. 3 illustrates a cross-sectional view of a display panel illustrated in FIG. 2 according to some embodiments of the present disclosure;

FIG. 4 is a plan view of a display panel illustrated in FIG. 2 according to some embodiments of the present disclosure;

FIG. 5 is a view illustrating a display device according to some embodiments of the present disclosure;

FIG. 6 is an exploded perspective view of a display device illustrated in FIG. 5 according to some embodiments of the present disclosure;

FIG. 7 is a view illustrating an equivalent circuit of one pixel among the pixels illustrated in FIG. 4 according to some embodiments of the present disclosure;

FIG. 8 is a timing diagram of signals for operating a pixel illustrated in FIG. 7 according to some embodiments of the present disclosure;

FIG. 9 is a cross-sectional view schematically illustrating a first transistor and a light-emitting element illustrated in FIG. 7 according to some embodiments of the present disclosure;

FIG. 10 is a view schematically illustrating a planar configuration of second and third transistors illustrated in FIG. 7 according to some embodiments of the present disclosure;

FIG. 11 is a cross-sectional view taken along the line I-I′ illustrated in FIG. 10 according to some embodiments of the present disclosure;

FIG. 12 is a cross-sectional view schematically illustrating a connection structure for a first transistor and a second transistor according to some embodiments of the present disclosure;

FIG. 13 is a cross-sectional view schematically illustrating a connection structure for a first transistor and a third transistor according to some embodiments of the present disclosure;

FIG. 14 is a view schematically illustrating a planar configuration of second and third transistors of a pixel according to Comparative Example; and

FIGS. 15 to 18 are views schematically illustrating a cross-sectional configuration of second and third transistors according to some embodiments of the present disclosure.

### DETAILED DESCRIPTION

In this specification, it will be understood that when an element (or region, layer, portion, or the like) is referred to as being “on”, “connected to” or “coupled to” another element, it may be directly located/connected/coupled to another element, or intervening elements may be located therebetween.

Like reference numerals or symbols refer to like elements throughout. Also, in the drawings, the thicknesses, the ratios, and the dimensions of the elements are exaggerated for effective description of the technical contents.

The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the spirit and scope of embodiments according to the present disclosure. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, aspects of some embodiments of the present disclosure will be described in more detail with reference to the accompanying drawings.

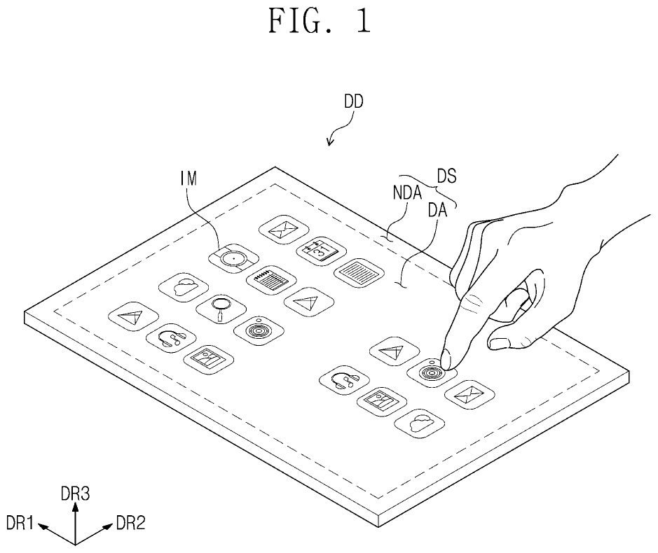

FIG. 1 is a perspective view of a display device according to some embodiments of the present disclosure.

Referring to FIG. 1, a display device DD according to some embodiments of the present disclosure may have a rectangular shape which has long sides extending in a first direction DR1 and short sides extending in a second direction DR2 crossing the first direction DR1. However, embodiments according to the present disclosure are not limited thereto, and the display device DD may have various shapes, such as a circular, elliptical, or polygonal shape.

Hereinafter, a direction, which is perpendicular to a plane defined by the first direction DR1 and the second direction DR2, is defined as a third direction DR3. In this specification, the wording “when viewed on a plane” or “in a plan view” may refer to a case when viewed from the third direction DR3.

An upper surface of the display device DD may be defined as a display surface DS and have a plane defined by the first direction DR1 and the second direction DR2. Images IM generated by the display device DD through the display surface DS may be provided to users in the third direction DR3.

The display surface DS may include a display region DA and a non-display region NDA around (e.g., in a periphery or outside a footprint of) the display region DA. The display region DA may display images, and the non-display region NDA may not display images. The non-display region NDA may surround the display region DA and define a border of the display device DD printed in a color (e.g., a set or predetermined color).

The display device DD may be used for large-sized electronic devices such as a television, a monitor, or an outdoor billboard. Additionally, the display device DD may be used for medium- and small-sized devices such as a personal computer, a laptop computer, a personal digital terminal, a car navigation unit, a game console, a smartphone, a tablet computer, or a camera. However, these are merely presented as examples, and the display device DD may also be employed in other electronic apparatuses without departing from the spirit and scope of embodiments according to the present disclosure.

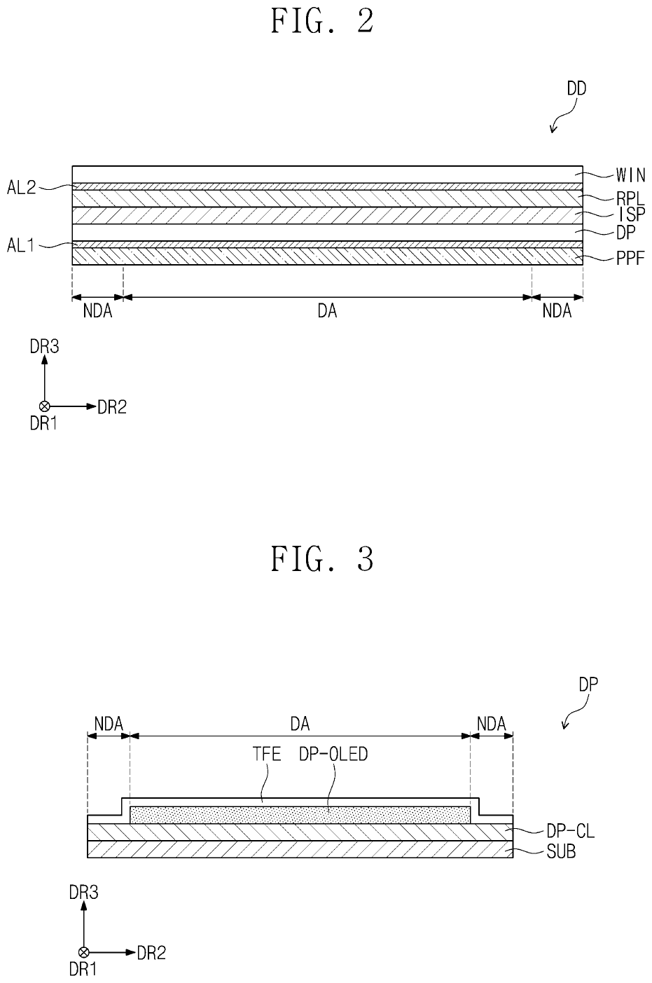

FIG. 2 illustrates a cross-sectional view of a display device illustrated in FIG. 1 according to some embodiments of the present disclosure.

For example, FIG. 2 illustrates a cross section of a display device DD when viewed in the first direction DR1.

Referring to FIG. 2, the display device DD may include a display panel DP, an input-sensing unit ISP, an anti-reflection layer RPL, a window WIN, a panel protection film PPF, and first and second adhesive layers AL1 and AL2.

The display panel DP may be a flexible display panel. The display panel DP according to some embodiments of the present disclosure may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, and the like. Hereinafter, the display panel DP is described as an organic light-emitting display panel.

The input-sensing unit ISP may be directly located on the display panel DP. The input-sensing unit ISP may include a plurality of sensor units for sensing an external input in a capacitive manner. The input-sensing unit ISP may be directly manufactured on the display panel DP when the display device DD is manufactured. However, embodiments according to the present disclosure are not limited thereto. The input-sensing unit ISP may be manufactured as a panel separately from the display panel DP and then attached to the display panel DP via an adhesive layer.

The anti-reflection layer RPL may be located on the input-sensing unit ISP. The anti-reflection layer RPL may be directly manufactured on the input-sensing unit ISP when the display device DD is manufactured. However, embodiments according to the present disclosure are not limited thereto. The anti-reflection layer RPL may be separately manufactured as a panel and then attached to the input-sensing unit ISP via an adhesive layer.

The anti-reflection layer RPL may be defined as an external light anti-reflection film. The anti-reflection layer RPL may relatively reduce the reflectance for external light that enters the display panel DP from above the display device DD. Due to the anti-reflection layer RPL, the external light may not be viewed by a user.

When external light propagating toward the display panel DP is reflected at the display panel DP and is re-provided to an external user, the external light may be viewed by the user as if reflected from a mirror. In order to prevent or relatively reduce this phenomenon, the anti-reflection layer RPL may include, for example, a plurality of color filters which display the same colors as pixels of the display panel DP.

The color filters may filter external light with the same colors as pixels. In this case, the external light may be invisible to users. However, embodiments according to the present disclosure are not limited thereto, and the anti-reflection layer RPL may include a retarder and/or a polarizer for relatively reducing the reflectance for external light.

The window WIN may be located on the anti-reflection layer RPL. The window WIN may protect the display panel DP, the input-sensing unit ISP, and the anti-reflection layer RPL against external scratches and impacts.

The panel protection film PPF may be located below the display panel DP. The panel protection film PPF may protect a lower part of the display panel DP. The panel protection film PPF may include a flexible plastic material such as polyethyleneterephthalate (PET).

The first adhesive layer AL1 may be located between the display panel DP and the panel protection film PPF, and the display panel DP and the panel protection film PPF may be bonded to each other via the first adhesive layer AL1. The second adhesive layer AL2 may be located between the window WIN and the anti-reflection layer RPL, and the window WIN and the anti-reflection layer RPL may be bonded to each other via the second adhesive layer AL2.

FIG. 3 illustrates a cross-sectional view of a display panel illustrated in FIG. 2 according to some embodiments of the present disclosure.

For example, FIG. 3 illustrates a cross section of a display panel DP when viewed in the first direction DR1.

Referring to FIG. 3, the display panel DP may include a substrate SUB, a circuit element layer DP-CL located on the substrate SUB, a display element layer DP-OLED located on the circuit element layer DP-CL, and a thin-film encapsulation layer TFE located on the display element layer DP-OLED.

The substrate SUB may include a display region DA and a non-display region NDA around the display region DA. The substrate SUB may include glass or a flexible plastic material such as polyimide (PI). The display element layer DP-OLED may be located at display region DA.

A plurality of pixels may be located on the circuit element layer DP-CL and the display element layer DP-OLED. The pixels may each include a transistor located on the circuit element layer DP-CL and a light-emitting element located on the display element layer DP-OLED and connected to the transistor.

The thin-film encapsulation layer TFE may be located on the circuit element layer DP-CL so as to cover the light-emitting element layer DP-OLED. The thin-film encapsulation layer TFE may protect the pixels against contaminants such as moisture, oxygen, and external foreign substances.

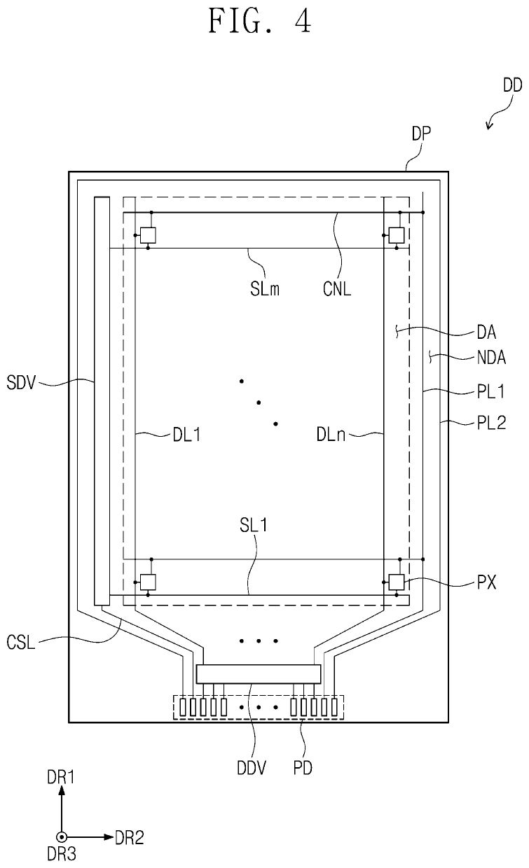

FIG. 4 is a plan view of a display panel illustrated in FIG. 2.

Referring to FIG. 4, a display device DD may include a display panel DP, a scan driver SDV, a data driver DDV, and a plurality of pads PD.

The display panel DP may have a rectangular shape which has long sides extending in the first direction DR1 and short sides extending in the second direction DR2. However, a shape of the display panel DP is not limited thereto. The display panel DP may include a display region DA and a non-display region NDA around the display region DA.

The display panel DP may include a plurality of pixels PX, a plurality of scan lines SL1 to SLm, a plurality of data lines DL1 to DLn, a control line CSL, first and second power supply lines PL1 and PL2, and connection lines CNL. m and n are natural numbers.

The pixels PX may be located in the display region DA. The pixels PX may be arranged in a matrix form, but an arrangement form of the pixels PX is not limited thereto.

The scan driver SDV may be located in the non-display region NDA adjacent to one long side among the long sides of the display panel DP. In a plan view, the scan driver SDV may be adjacent to a left side of the display panel DP.

The data driver DDV may be located in the non-display region NDA adjacent to one short side among the short sides of the display panel DP. In a plan view, the data driver DDV may be adjacent to a lower end of the display panel DP.

The scan lines SL1 to SLm may extend in the second direction DR2 to be connected to the pixels PX and the scan driver SDV. The data lines DL1 to DLn may extend in the first direction DR1 to be connected to the pixels PX and the data driver DDV.

The first power supply line PL1 may extend in the first direction DR1, and may be located in the non-display region NDA. The first power supply line PL1 may be adjacent to a long side of the display panel DP in which the scan driver SDV is not located.

The connection lines CNL may extend in the second direction DR2, and may be arranged in the first direction DR1 to be connected to the first power supply line PL1 and the pixels PX. A first voltage may be applied to the pixels PX via the first power supply line PL1 and the connection lines CNL which are connected to each other.

The second power supply line PL2 may be located in the non-display region NDA and extend along the long sides of the display panel DP and the other short side of the display panel DP in which the data driver DDV is not located. The second power supply line PL2 may be located further outside than the scan driver SDV.

According to some embodiments, the second power supply line PL2 may extend toward the display region DA to be connected to the pixels PX. A second voltage may be applied to the pixels PX via the second power supply line PL2.

The control line CSL may be connected to the scan driver SDV and extend toward a lower end of the display panel DP. A control signal for controlling an operation of the scan driver SDV may be provided to the scan driver SDV via the control line CSL.

The pads PD may be located in the non-display region NDA adjacent to the lower end of the display panel DP, and may be further adjacent to the lower end of the display panel DP than the data driver DDV. The data driver DDV, the first and second power supply lines PL1 and PL2, and the control line CSL may be connected to the pads PD. The data lines DL1 to DLn may be connected to the data driver DDV, and the data driver DDV may be connected to the pads PD corresponding to the data lines DL1 to DLn.

According to some embodiments, the display device DD may further include a timing controller for controlling operations of the scan driver SDV and the data driver DDV, and a voltage generator for generating the first and the second voltages. The timing controller and the voltage generator may be mounted on a printed circuit board and connected to the pads PD via the printed circuit board.

The scan driver SDV may generate a plurality of scan signals, and the scan signals may be applied to the pixels PX via the scan lines SL1 to SLm. The data driver DDV may generate a plurality of data voltages, and the data voltages may be applied to the pixels PX via the data lines DL1 to DLn.

The pixels PX may receive data voltages in response to the scan signals. The pixels PX may display images by emitting light having a luminance corresponding to the data voltages.

According to some embodiments of the present disclosure, the sizes of the pixels PX of the display panel DP may be relatively reduced, and a structure of the pixels PX will be described below in more detail.

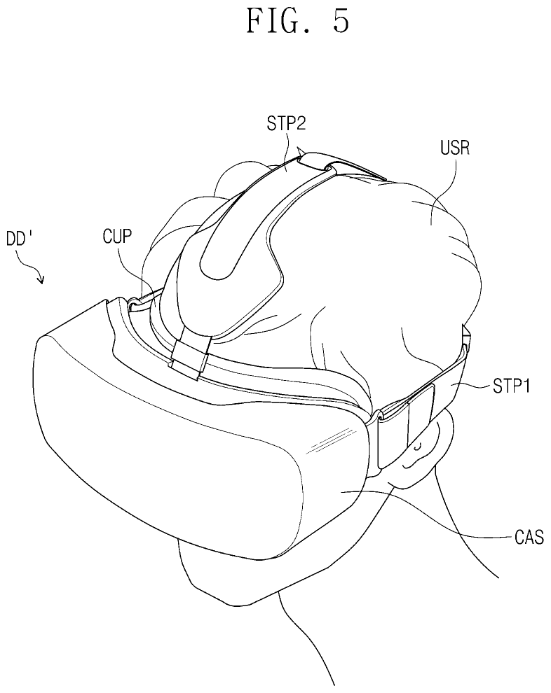

FIG. 5 is a view illustrating a display device according to some embodiments of the present disclosure.

Referring to FIG. 5, a display device DD′ according to some embodiments of the present disclosure may be defined as a head-mounted display device. The display device DD′ may be worn on the head of a user USR.

The display device DD′ may provide images to the user USR by blocking a peripheral visual field of the user USR. The display device DD′ may provide virtual reality to the user USR.

The display device DD′ may include a case part CAS, a cushion part CUP, and strap parts STP1 and STP2. The case part CAS may be worn on the user USR. A display panel DP for displaying images, an acceleration sensor, etc., may be accommodated inside the case part CAS. The display panel DP may be the display panel DP illustrated in FIG. 4.

The acceleration sensor may detect movements of the user USR and transmit a signal (e.g., a set or predetermined signal) to the display panel DP. Therefore, the display panel DP may provide images corresponding to changes in gaze of the user USR. As a result, the user USR may experience virtual reality as if actual reality.

The cushion part CUP may be located between the case part CAS and the user USR. The window CUP may include a freely deformable material. For example, the cushion part CUP may include polymer resins (for example, polyurethane, polycarbonate, polypropylene, and polyethylene). Additionally, the cushion part CUP may include a sponge obtained by foaming a rubber solution, a urethane-based material, or an acrylic-based material.

The cushion part CUP may allow the case part CAS to be in close contact with the user USR, thereby improving wearing comfort for the user USR. The cushion part CUP may be detachable from the case part CAS.

The strap parts STP1 and STP2 are coupled to the case part CAS, which allows the case part CAS to be easily worn by the user USR. The strap parts STP1 and STP2 may include a first strap STP1 and a second strap STP2.

The first strap STP1 may be worn along a circumference of the head of the user USR. The first strap STP1 may fix the case part CAS to the user USR such that the case part CAS is able to closely contact the head of the user USR.

The second strap STP2 may connect the case part CAS and the first strap STP1 along the top of the head of the user USR. The second strap STP2 may prevent or relatively reduce instances of the case part CAS falling down.

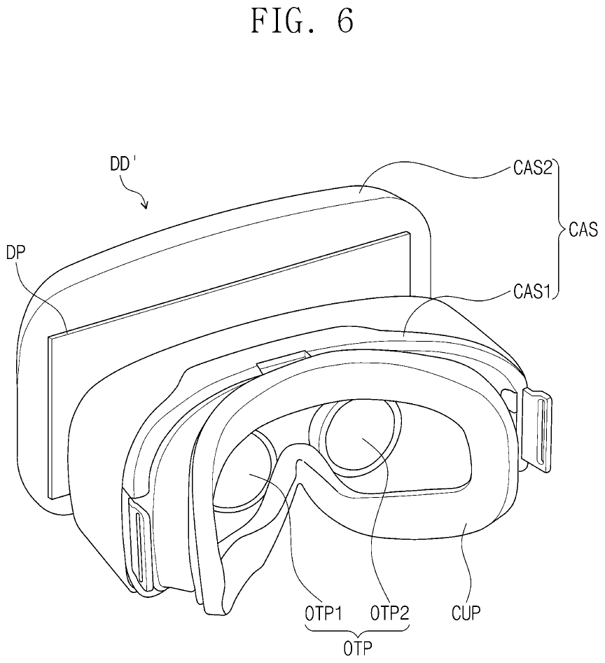

FIG. 6 is an exploded perspective view of the display device illustrated in FIG. 5.

Referring to FIG. 6, a case part CAS may include a first case CAS1 and a second case CAS2. The first case CAS1 and the second case CAS2 may be separated from each other.

The display panel DP may be located between the first case CAS1 and the second case CAS2. The first case CAS1 and the second case CAS2 are coupled to each other, and the display panel DP may be accommodated inside the case part CAS. For example, the display panel DP may provide a left-eye image and a right-eye image to a user. Accordingly, the display panel DP may display three-dimensional images to a user.

An optical system OTP may be located inside the first case CAS1. The optical system OTP may enlarge an image provided from the display panel DP. The optical system OTP may be located between the display panel DP and eyes of the user USR. The optical system OTP may include a left-eye optical system OTP1 and a right-eye optical system OTP2. The left-eye optical system OTP1 may enlarge an image in the left pupil of the user USR and provide the image to the user USR, and the right-eye optical system OTP2 may enlarge an image in the right pupil of the user USR and provide the image to the user USR.

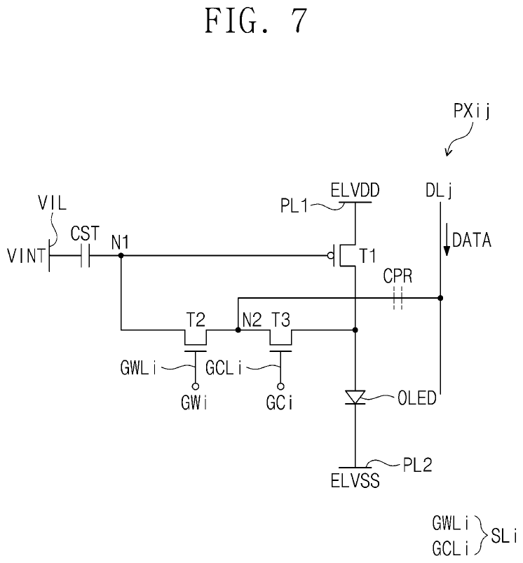

FIG. 7 is a view illustrating an equivalent circuit of one pixel among the pixels illustrated in FIG. 4. Although various components are illustrated in FIG. 7, embodiments according to the present disclosure are not limited thereto. For example, in some embodiments the circuit of the pixel may include additional components or fewer components without departing from the spirit and scope of embodiments according to the present disclosure.

For example, FIG. 7 illustrates a pixel PXij connected to an i-th scan line SLi and a j-th data line DLj. i and j are natural numbers. Hereinafter, for convenience of description, the terms “i-th” and “j-th” are omitted.

Referring to FIG. 7, the pixel PXij may include a first transistor T1, a second transistor T2, a third transistor T3, a light-emitting element OLED, and a capacitor CST.

The scan line SLi may include a write scan line GWLi and a compensation scan line GCLi. The write scan line GWLi may receive a write scan signal GWi, and the compensation scan line GCLi may receive a compensation scan signal GCi.

A parasitic capacitor CPR may be unintentionally formed between the data line DLj and a second node N2 between the second transistor T2 and the third transistor T3. However, because the parasitic capacitor CPR is not a component of the pixel PXij, a description of the parasitic capacitor CPR will be omitted when illustrating an operation of the pixel PXij.

The first transistor T1 may be a PMOS transistor. The second and third transistors T2 and T3 may be NMOS transistors. The first, second, and third transistors T1, T2, and T3 may each include a source electrode, a drain electrode, and a gate electrode. Hereinafter, in FIG. 7, for convenience, one among the source electrode and the drain electrode is defined as a first electrode, and the other is defined as a second electrode. Additionally, the gate electrode is defined as a control electrode.

The first transistor T1 may be defined as a driving transistor, and the second transistor T2 may be defined as a switching transistor. The third transistor T3 may be defined as a compensation transistor.

The first transistor T1 may be connected to a first power supply line PL1 and the light-emitting element OLED, and may be switched according to a voltage of a first node N1. The first power supply line PL1 may receive a first voltage ELVDD.

The first transistor T1 may include a first electrode connected to the first power supply line PL1, a second electrode connected to the anode of the light-emitting element OLED, and a control electrode connected to the first node N1. The first transistor T1 may be turned on by the voltage of the first node N1. The first node N1 may be defined by the control electrode of the first transistor T1.

The second transistor T2 may be connected to the first node N1 and the second node N2, and may be switched by the write scan signal GWi. The second transistor T2 may include a first electrode connected to the first node N1, a second electrode connected to the second node N2, and a control electrode connected to the write scan line GWLi. The second transistor T2 may be turned on by the write scan signal GWi applied via the write scan line GWLi.

The third transistor T3 may be connected to the second node N2 and the light-emitting element OLED and switched by the compensation scan signal GCi. The third transistor T3 may include a first electrode connected to the second node N2, a second electrode connected to the anode of the light-emitting element OLED, and a control electrode connected to the compensation scan line GCLi. The third transistor T3 may be turned on by the compensation scan signal GCi applied via the compensation scan line GCLi.

The second transistor T2 may be turned on by an activated write scan line GWLi. The third transistor T3 may be turned on by an activated compensation scan signal GCi. Because the second and third transistors T2 and T3 are NMOS transistors, the activated write scan signal GWi and the activated compensation scan signal GCi may be defined as high-level signals.

The data line DLj may be connected to the second node N2. Accordingly, the data line DLj may be connected to the second electrode of the second transistor T2 and the first electrode of the third transistor T3. The data line DLj may receive a data signal DATA.

The anode of the light-emitting element OLED may be connected to the first power supply line PL1 via the first transistor T1, and the cathode of the light-emitting element OLED may be connected to the second power supply line PL2. The second power supply line PL2 may receive a second voltage ELVSS.

The capacitor CST may include a first electrode connected to an initialization line VIL and a second electrode connected to the first node N1. The initialization line VIL may receive an initialization voltage VINT.

The write scan signal GWi applied to the control electrode of the second transistor T2 may be a global clock signal for simultaneous (or concurrent) emission driving. For example, when the display device DD is operated in a simultaneous (or concurrent) emission driving manner, the write scan signal GWi, which is a global clock signal, may be applied to the pixels PX in common.

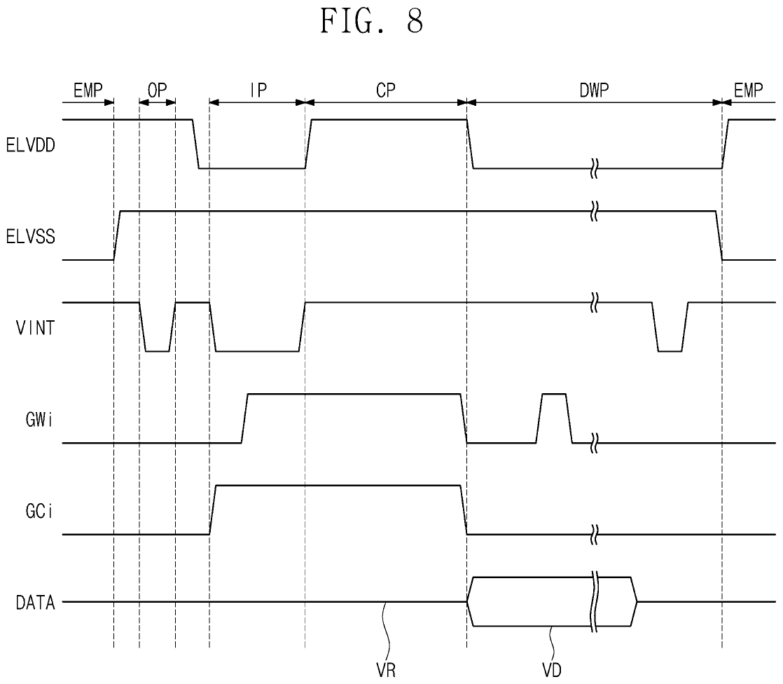

FIG. 8 is a timing diagram of signals for operating the pixel illustrated in FIG. 7.

Referring to FIGS. 7 and 8, an operation section of a pixel PXij may include an on-bias section OP, an initialization section IP, a compensation section CP, a data write section DWP, and an emission section EMP.

The pixel PXij may perform an on-bias operation in the on-bias section OP, and perform an initialization operation in the initialization section IP. The pixel PXij may perform a threshold voltage compensation operation in the compensation section CP, perform a data write operation in the data write section DWP, and perform an emission operation in the emission section EMP.

In the on-bias section OP, the first voltage ELVDD may have a high voltage level, the second voltage ELVSS may have a high voltage level, and the initialization voltage VINT may have a low voltage level. In the on-bias section OP, the write scan signal GWi and the compensation scan signal GCi may each have a low level (for example, deactivated level), and the data signal DATA may have a reference voltage VR having a preset level.

In this case, an on-bias operation is performed on the pixel PXij, and thus a voltage characteristic curve of the first transistor T1 may be initialized to an on-bias state regardless of the data signal DATA supplied in the previous frame. As a result, the pixel PXij may generate the desired luminance regardless of the data signal DATA supplied in the previous frame.

In the on-bias section OP, the initialization voltage VINT having a low voltage level is delivered to a gate terminal of the first transistor T1. However, both of the first voltage ELVDD and the second voltage ELVSS have high voltage levels, and thus the first transistor T1 may not be turned on. The second and third transistors T2 and T3 may be turned off according to the write scan signal GWi and the compensation scan signal GCi, which are deactivated.

Thereafter, in the initialization section IP, the first voltage ELVDD may have a low voltage level, the second voltage ELVSS may have a high voltage level, and the initialization voltage VINT may have a low voltage level. In the initialization section IP, the write scan signal GWi may transition from a low level to a high level (for example, activated level), the compensation scan signal GCi may have a high level (for example, activated level), and the data signal DATA may have the reference voltage VR.

Accordingly, the second transistor T2 may be turned off and then turned on, and the third transistor T3 may be turned on. Because the second and third transistors T2 and T3 are turned on, the first node N1 may be connected to the second node N2, and the second node N2 may be connected to the anode of the light-emitting element OLED. According to the initialization voltage VINT, the first node (that is, control electrode of first transistor T1) may be initialized, the second node N2 connected to the first node N1 may be initialized, and the anode of the light-emitting element OLED connected to the second node N2 may be initialized.

Thereafter, in the compensation section CP, the first voltage ELVDD may have a high voltage level, the second voltage ELVSS may have a high voltage level, and the initialization voltage VINT may have a high voltage level. In the compensation section CP, the write scan signal GWi may have a high level, the compensation scan signal GCi may have a high level, and the data signal DATA may have the reference voltage VR.

The first transistor T1, the second transistor T2, and the third transistor T3 may be connected in a diode form. In this case, a voltage reflecting a threshold voltage of the first transistor is stored in the first node N1, and thus the characteristic deviation according to the threshold voltage of the first transistor T1 may be eliminated. An operation of connecting the first transistor T1 in a diode form may be defined as a threshold voltage compensation operation.

Thereafter, in the data write section DWP, the first voltage ELVDD may have a low voltage level, and the second voltage ELVSS may have a high voltage level. In the data write section DWP, when a time (e.g., a set or predetermined time) elapses after transition of the initialization voltage VINT from a high voltage level to a low voltage level, the initialization voltage VINT may transition from a low voltage level to a high voltage level.

In the data write section DWP, when a time (e.g., a set or predetermined time) (for example, data write operation time) elapses after transition of the write scan signal GWi from a low level to a high level, the write scan signal GWi may transition from a high level to a low level. In the data write section DWP, the compensation scan signal GCi may have a low level, and the data signal DATA may have a data voltage VD having a level corresponding to a gray level (e.g., a set or predetermined gray level).

The second transistor T2 may be turned on during a section (for example, high level) in which the write scan signal GWi is activated, and the third transistor T3 may be turned off. The data signal DATA may be stored in the capacitor CST during the data writing operation time when the second transistor T2 is turned on.

Thereafter, in the emission section EMP, the first voltage ELVDD may have a high voltage level, the second voltage ELVSS may have a low voltage level, and the initialization voltage VINT may have a high voltage level. The write scan signal GWi may have a low level, the compensation scan signal GCi may have a low level, and the data signal DATA may have the reference voltage VR.

In this case, the first transistor T1 may be turned on on the basis of the data signal DATA stored in the capacitor CST. Therefore, an electric current flows to the light-emitting element OLED, and thus the light-emitting element OLED may emit light.

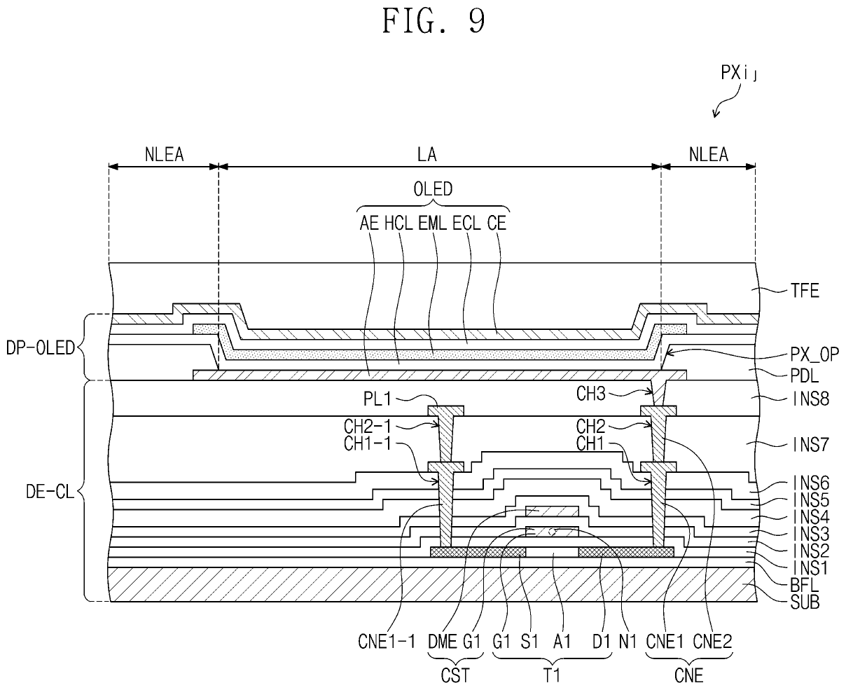

FIG. 9 is a cross-sectional view schematically illustrating the first transistor and the light-emitting element illustrated in FIG. 7.

Referring to FIG. 9, a light-emitting element OLED may include a first electrode AE, a second electrode CE, a hole control layer HCL, an electron control layer ECL, and a light-emitting layer EML. The first electrode AE may be an anode AE illustrated in FIG. 5, and the second electrode CE may be a cathode CE illustrated in FIG. 5. The second electrode CE may be located on the first electrode AE, and the hole control layer HCL, the electron control layer ECL, and the light-emitting layer EML may be located between the first electrode AE and the second electrode CE.

A first transistor T1 and the light-emitting element OLED may be located on a substrate SUB. A display region DA may include a light-emitting region LA corresponding to a pixel PXij and a non-light-emitting region NLA adjacent to the light-emitting region LA. The light-emitting element OLED may be located in the light-emitting region LA.

A buffer layer BFL may be located on the substrate SUB. First semiconductor layers S1, A1, and D1 of the first transistor T1 may be located on the buffer layer BFL. The first semiconductor layers S1, A1, and D1 may include polysilicon. However, embodiments according to the present disclosure are not limited thereto, and the first semiconductor layers S1, A1, and D1 may include amorphous silicon.

The first semiconductor layers S1, A1, and D1 may be doped with an N-type dopant or a P-type dopant. The first semiconductor layers S1, A1, and D1 may include a heavily doped region and a lightly doped region. The conductivity of the highly doped region is greater than that of the lightly doped region, and may serve as a source electrode and drain electrode of the first transistor T1. The lightly doped region may correspond to an active (or channel) of the first transistor T1.

The first semiconductor layers S1, A1, and D1 may include a first source region S1, a first channel region A1, and a first drain region D1. The first channel region A1 may be located between the first source region S1 and the first drain region D1. The first source region S1 may be a first electrode of the first transistor T1 described above. The first drain region D1 may be a second electrode of the first transistor T1 described above. Accordingly, the first semiconductor layers S1, A1, and D1 may be connected to a first power supply line PL1 and the light-emitting element OLED.

A first insulating layer INS1 may be located on the buffer layer BFL so as to cover the first semiconductor layers S1, A1, and D1. A first gate electrode G1 of the first transistor T1 may be located on the first insulating layer INS1. In a plan view, the first gate electrode G1 may overlap the first channel region A1. The first gate electrode G1 may be connected to a first node N1 as a control electrode of the first transistor T1 described above. According to some embodiments, the first gate electrode G1 may serve as the first node N1.

A second insulating layer INS2 may be located on the first insulating layer INS1 so as to cover the first gate electrode G1. A dummy electrode DME may be located on the second insulating layer INS2. The dummy electrode DME may form the above-described capacitor CST together with the first gate electrode G1. The first gate electrode G1 may define a first electrode of the capacitor CST, and the dummy electrode DME may define a second electrode of the capacitor CST.

A third insulating layer INS3 may be located on the second insulating layer INS2 so as to cover the dummy electrode DME. A fourth insulating layer INS4 may be located on the third insulating layer INS3, a fifth insulating layer INS5 may be located on the fourth insulating layer INS4, and a sixth insulating layer INS6 may be located on the fifth insulating layer INS5. The buffer layer BFL and the first to sixth insulating layers INS1 to INS5 may include inorganic layers. The fourth and sixth insulating layers INS4 and INS6 may be thicker than other insulating layers INS1 to INS3, and INS5.

A connection electrode CNE may be located between the first transistor T1 and the light-emitting element OLED. The connection electrode CNE may electrically connect the first transistor T1 and the light-emitting element OLED. The connection electrode CNE may include a first connection electrode CNE1 and a second connection electrode CNE2 located on the first connection electrode CNE1.

The first connection electrode CNE1 may be located on the sixth insulating layer INS6, and may be connected to the first drain region D1 via a first contact hole CH1 defined in the first to sixth insulating layers INS1 to INS6. A seventh insulating layer INS7 may be located on the sixth insulating layer INS6 so as to cover the first connection electrode CNE1.

The second connection electrode CNE2 may be located on the seventh insulating layer INS7. The second electrode CNE2 may be connected to the first connection electrode CNE1 via a second contact hole CH2 defined in the seventh insulating layer INS7. An eighth insulating layer INS8 may be located on the seventh insulating layer INS7 so as to cover the second connection electrode CNE2.

A first connection electrode CNE1-1 may be located on the sixth insulating layer INS6. The first connection electrode CNE1-1 may be connected to the first source region S1 via a first contact hole CH1-1 defined in the first to sixth insulating layers INS1 to INS6. The seventh insulating layer INS7 may be located on the sixth insulating layer INS6 so as to cover the first connection electrode CNE1-1.

The first power supply line PL1 may be located on the seventh insulating layer INS7. The first power supply line PL1 may be connected to the first connection electrode CNE1-1 via a second contact hole CH2-1 defined in the seventh insulating layer INS7. The eighth insulating layer INS8 may be located on the seventh insulating layer INS7 so as to cover the first power supply line PL1. According to this structure, the first semiconductor layers S1, A1, and D2 may be connected to the first power supply line PL1.

The first electrode AE may be located on the eighth insulating layer INS8. The first electrode AE may be electrically connected to the second connection electrode CNE2 via a third contact hole CH3 defined in the eighth insulating layer INS8. Accordingly, the first drain region D1 may be connected to the light-emitting element OLED via the connection electrode CNE. According to this structure, the first semiconductor layers S1, A1, and D2 may be connected to the light-emitting element OLED.

A pixel-defining film PDL which exposes a portion (e.g., a set or predetermined portion) of the first electrode AE may be located on the first electrode AE and the eighth insulating layer INS8. An opening PX_OP for exposing a portion (e.g., a set or predetermined portion) of the first electrode AE may be defined in the pixel-defining film PDL.

The hole control layer HCL may be located on the first electrode AE and the pixel-defining film PDL. The hole control layer HCL may be located in the light-emitting region LA and the non-light-emitting region NLA in common. The hole control layer HCL may include a hole transport layer and a hole injection layer.

The light-emitting layer EML may be located on the hole control layer HCL.

The light-emitting layer EML may be located in a region corresponding to the opening PX_OP. The light-emitting layer EML may include an organic material and/or an inorganic material. The light-emitting layer EML may generate light having one color of red, green, or blue.

The electron control layer ECL may be located on the light-emitting layer EML and the hole control layer HCL. The electron control layer ECL may be located in the light-emitting region LA and the non-light-emitting region NLA in common. The electron control layer ECL may include an electron transport layer and an electron injection layer.

The second electrode CE may be located on the electron control layer ECL. The second electrode CE may be located in pixels PX in common. That is, the second electrode CE may be located on the light-emitting layers EML of the pixels PX, in common.

The layers, including the buffer layer BFL to the eighth insulating layer INS8, may be defined as a circuit element layer DP-CL. The layer on which the light-emitting element OLED is located may be defined as a display element layer DP-OLED.

A thin-film encapsulation layer TFE may be located on the light-emitting element OLED. The thin-film encapsulation layer TFE may include an inorganic layer, an organic layer, and an inorganic layer which are sequentially stacked. The inorganic layers may include an inorganic material and protect the pixels against moisture/oxygen. The organic layer may include an organic material and protect the pixels PX against foreign substances or contaminants such as dust particles or moisture.

The first voltage ELVDD may be applied to the first electrode AE, and the second voltage ELVSS may be applied to the second electrode CE. Holes and electrons injected into the light-emitting layer EML are combined to form excitons, and the excitons transition to a ground state, so that the light-emitting element OLED may emit light. The light-emitting element OLED emits light, and thus an image may be displayed.

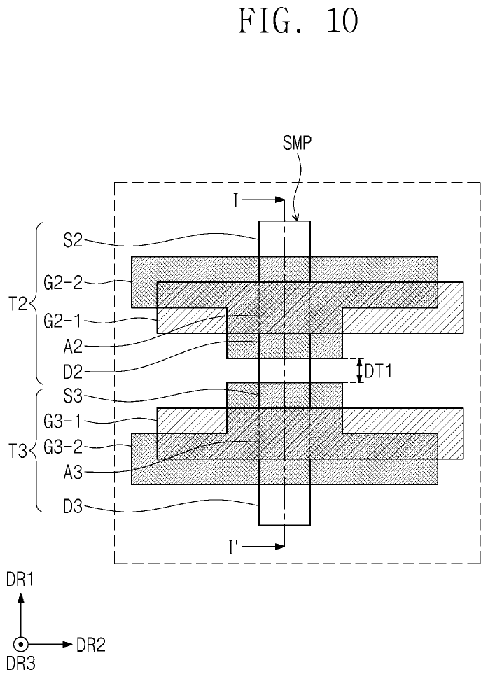

FIG. 10 is a view schematically illustrating a planar configuration of second and third transistors illustrated in FIG. 7.

Referring to FIG. 10, a second transistor T2 and a third transistor T3 may be arranged in the first direction DR1. The second transistor T2 and the third transistor T3 may each have a structure symmetrical with respect to the first direction DR1.

A semiconductor pattern SMP may extend in the first direction DR1. Second semiconductor layers S2, A2, and D2 of the second transistor T2, and third semiconductor layers S3, A3, and D3 of the third transistor T3 may be formed by the semiconductor pattern SMP.

The second semiconductor layers S2, A2, and D2 may include a second source region S2, a second channel region A2, and a second drain region D2. The second channel region A2 may be located between the second source region S2 and the second drain region D2.

The second source region S2 may be the first electrode of the second transistor T2 described above, and the second drain region D2 may be the second electrode of the second transistor T2 described above. Accordingly, the second semiconductor layers S2, A2, and D2 may be connected to the first node N1 and the second node N2. The second source region S2 may be connected to the first node N1, and the second drain region D2 may be connected to the second node N2.

The third semiconductor layers S3, A3, and D3 may include a third source region S3, a third channel region A3, and a third drain region D3. The third channel region A3 may be located between the third source region S3 and the third drain region D3.

The third source region S3 may be the first electrode of the third transistor T3 described above, and the third drain region D3 may be the second electrode of the third transistor T3 described above. Accordingly, the third semiconductor layers S3, A3, and D3 may be connected to the second node N2 and the light-emitting element OLED. The third source region S3 may be connected to the second node N2, and the third drain region D3 may be connected to the light-emitting element OLED.

The second semiconductor layers S2, A2, and D2, and the third semiconductor layers S3, A3, and D3 may be integrally formed. For example, the third source region S3 may be formed by extension from the second drain region D2.

The gate electrode of the second transistor T2 may include a (2-1)-th gate electrode G2-1 and a (2-2)-th gate electrode G2-2. The (2-1)-th gate electrode G2-1 may extend in the second direction DR2. The (2-1)-th gate electrode G2-1 may extend to cross the second semiconductor layers S2, A2, and D2. A portion, of the second semiconductor layers S2, A2, and D2, overlapping the (2-1)-th gate electrode G2-1 may be defined as the second channel region A2.

The (2-2)-th gate electrode G2-2 may have a T-shape and extend to cross the second semiconductor layers S2, A2, and D2. In order to have a T-shape, the (2-2)-th gate electrode G2-2 may extend in the second direction DR2, and a portion of the (2-2)-th gate electrode G2-2 may protrude in the first direction DR1. The (2-2)-th gate electrode G2-2 may partially overlap the (2-1)-th gate electrode G2-1. In a plan view, the (2-2)-th gate electrode G2-2 may have an area greater than that of the second channel region A2 so as to cover the second channel region A2.

The gate electrode of the third transistor T3 may include a (3-1)-th gate electrode G3-1 and a (3-2)-th gate electrode G3-2. The (3-1)-th gate electrode G3-1 may extend in the second direction DR2. The (3-1)-th gate electrode G3-1 may extend to cross the third semiconductor layers S3, A3, and D3. A portion, of the third semiconductor layers S3, A3, and D3, overlapping the (3-1)-th gate electrode G3-1 may be defined as the third channel region A3.

The (3-2)-th gate electrode G3-2 may have a T-shape and extend to cross the third semiconductor layers S3, A3, and D3. In order to have a T-shape, the (3-2)-th gate electrode G3-2 may extend in the second direction DR2, and a portion of the (3-2)-th gate electrode G3-2 may protrude in the first direction DR1. The portion, of the (2-2)-th gate electrode G2-2, protruding in the first direction DR1, and the portion, of the (3-2)-th gate electrode G3-2, protruding in the first direction DR1 may face each other.

The (3-2)-th gate electrode G3-2 may have a shape symmetrical to the (2-2)-th gate electrode G2-2. The (3-2)-th gate electrode G3-2 may partially overlap the (3-1)-th gate electrode G3-1. In a plan view, the (3-2)-th gate electrode G3-2 may have an area greater than that of the third channel region A3 so as to cover the third channel region A3.

According to the above-described structure, the second transistor T2 may include the second source region S2, the second channel region A2, the second drain region D2, the (2-1)-th gate electrode G2-1, and the (2-2)-th gate electrode G2-2. Also, the third transistor T3 may include the third source region S3, the third channel region A3, the third drain region D3, the (3-1)-th gate electrode G3-1, and the (3-2)-th gate electrode G3-2.

The (2-2)-th gate electrode G2-2 may be spaced apart from the (3-2)-th gate electrode G3-2 by a first distance DT1 in the first direction DR1. The first distance DT1 may be defined as a distance between the portion, of the (2-2)-th gate electrode G2-2, protruding in the first direction DR1 and the portion, of the (3-2)-th gate electrode G3-2, protruding in the first direction DR1. The first distance DT1 may be about 0.5 μm to about 1.5 μm.

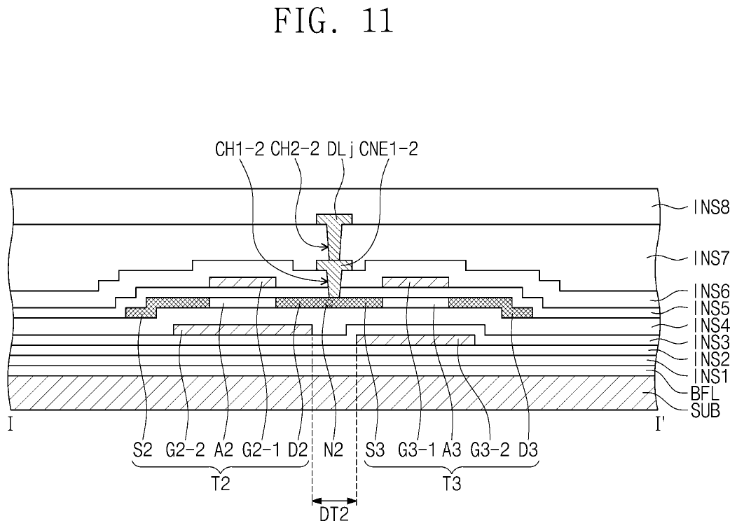

FIG. 11 is a cross-sectional view taken along the line I-I′ illustrated in FIG. 10.

For example, in FIG. 11, a cross section of the light-emitting element OLED is omitted.

Referring to FIG. 11, a buffer layer BFL, a first insulating layer INS1, and a second insulating layer INS2 may be located on a substrate SUB. A (3-2)-th gate electrode G3-2 may be located on the second insulating layer INS2. A third insulating layer INS3 may be located on the second insulating layer INS2 so as to cover the (3-2)-th gate electrode G3-2. A (2-2)-th gate electrode G2-2 may be located on the third insulating layer INS3. A fourth insulating layer INS4 may be located on the third insulating layer INS3 so as to cover the (2-2)-th gate electrode G2-2.

Second semiconductor layers S2, A2, and D2, and third semiconductor layers S3, A3, and D3 may be located on the fourth insulating layer INS4. The second semiconductor layers S2, A2, and D2, and the third semiconductor layers S3, A3, and D3 may include an oxide semiconductor formed of a metal oxide. The oxide semiconductor may include a crystalline or amorphous oxide semiconductor.

The second semiconductor layers S2, A2, and D2, and the third semiconductor layers S3, A3, and D3 may each include a plurality of regions distinguished according to whether a metal oxide is relatively reduced. A region in which a metal oxide is relatively reduced (hereinafter, referred to as reduced region) has conductivity higher than that of a region in which a metal oxide is not reduced (hereinafter, referred to as non-reduced region). The reduced region may serve as a source electrode or a drain electrode of each of the second and third transistors T2 and T3. The non-reduced region may correspond to an active (or channel) of each of the second and third transistors T2 and T3.

The third semiconductor layers S3, A3, and D3 may be formed by extension from the second semiconductor layers S2, A2, and D2. The second channel region A2 may be located between the second source region S2 and the second drain region D2, and the third channel region A3 may be located between the third source region S3 and the third drain region D3.

The (2-2)-th gate electrode G2-2 may have an area greater than that of the second channel region A2, be located below the second channel region A2, and cover the second channel region A2. The (3-2)-th gate electrode G3-2 may have an area greater than that of the third channel region A3, be located below the third channel region A3, and cover the third channel region A3.

The (2-2)-th gate electrode G2-2 may block light provided from below the substrate SUB toward the second channel region A2. The (3-2)-th gate electrode G3-2 may block light provided from below the substrate SUB toward the third channel region A3.

When light is provided to the second and third channel regions A2 and A3, the light may cause the threshold voltage characteristics of the second and third transistors A2 and A3 to be changed (for example, a threshold voltage is shifted). To prevent or relatively reduce this phenomenon, the (2-2)-th and (3-2)-th gate electrodes G2-2 and G3-2 may block light provided from below the substrate SUB toward the second and third channel regions A2 and A3.

A second node N2 may be defined between the second semiconductor layers S2, A2, and D2 and the third semiconductor layers S3, A3, and D3. A portion, of the semiconductor layer, between the third source region S3 and the second drain region D2 may be defined as the second node N2. That is, the second semiconductor layers S2, A2, and D2, and the third semiconductor layers S3, A3, and D3 may be connected to the second node N2. The fourth insulating layer INS4 may be located on the third insulating layer INS3 so as to cover the second semiconductor layers S2, A2, and D2, and the third semiconductor layers S3, A3, and D3.

The (2-1)-th gate electrode G2-1 and the (3-1)-th gate electrode G3-1 may be located on the fourth insulating layer INS4. In a plan view, the (2-1)-th gate electrode G2-1 may overlap the second channel region A2. In a plan view, the (3-1)-th gate electrode G3-1 may overlap the third channel region A3.

According to the structure, the (2-1)-th gate electrode G2-1 may be located on the second semiconductor layers S2, A2, and D2, and the (2-2)-th gate electrode G2-2 may be located below the second semiconductor layers S2, A2, and D2. The (3-1)-th gate electrode G3-1 may be located on the third semiconductor layers S3, A3, and D3, and the (3-2)-th gate electrode G3-2 may be located below the third semiconductor layers S3, A3, and D3.

The (2-2)-th gate electrode G2-2 and the (3-2)-th gate electrode G3-2 may be located on layers above the first gate electrode G1 illustrated in FIG. 9. For example, the second insulating layer INS2 may be located on the first transistor T1, and specifically, the second insulating layer INS2 may be located on the first gate electrode G1. The (2-2)-th gate electrode G2-2 and the (3-2)-th gate electrode G3-2 may located on the second insulating layer INS2, and thus be located on layers above the first gate electrode G1.

The (2-2)-th gate electrode G2-2 and the (3-2)-th gate electrode G3-2 may be located on different layers. For example, the (2-2)-th gate electrode G2-2 may be located on a layer above the (3-2)-th gate electrode G3-2.

A sixth insulating layer INS6 may be located on a fifth insulating layer INS5 so as to cover the (2-1)-th gate electrode G2-1 and the (3-1)-th gate electrode G3-1. A first connection electrode CNE1-1 may be located on the sixth insulating layer INS6. The first connection electrode CNE1-1 may be connected to the second node N2 via a first contact hole CH1-2 defined in the sixth insulating layer INS6.

A seventh insulating layer INS7 may be located on the sixth insulating layer INS6 so as to cover the first connection electrode CNE1-1. A data line DLj may be located on the seventh insulating layer INS7. The data line DLj may be connected to the first connection electrode CNE1-1 via a second contact hole CH2-2 defined in the seventh insulating layer INS7. An eighth insulating layer INS8 may be located on the data line DLj and the seventh insulating layer INS7.

The write scan signal GWi described above may be applied to the (2-1)-th gate electrode G2-1 and the (2-2)-th gate electrode G2-2. When the (2-1)-th gate electrode G2-1 and the (2-2)-th gate electrode G2-2 are respectively located above and below the second semiconductor layers S2, A2, and D2, the electron mobility of the second transistor T2 may be improved.

The compensation scan signal GCi described above may be applied to the (3-1)-th gate electrode G3-1 and the (3-2)-th gate electrode G3-2. When the (3-1)-th gate electrode G3-1 and the (3-2)-th gate electrode G3-2 are respectively located above and below the third semiconductor layers S3, A3, and D3, the electron mobility of the third transistor T3 may be improved.

Table 1 below shows the driving characteristics of each of the second transistor T2 and the third transistor T3.

TABLE 1

| | | DR range | | |
|---|---|---|---|---|
| TR type | Vth (V) | (V) | Mobility (cm²/Vs) | Ion (μA) |
| T2 | −1.23 | 2.05 | 7.2 | 5.00 |
| T3 | −1.22 | 2.08 | 6.9 | 4.89 |

In Table 1, Vth represents a threshold voltage, and DR range represents, in a transfer curve (Id-Vg) of a transistor, the amount of change in a gate voltage in a specific range of a drain current. For example, the DR range may represent the amount of change in the gate voltage in a range in which the drain current of the transfer curve has about 1 μA to about 1 pA. The difference value between the gate voltage corresponding to about 1 μA and the gate voltage corresponding to about 1 pA may be defined as the DR range, and a unit thereof is a volt V. In Table 1, Mobility represents an electron mobility, and Ion represents a current flowing in the transistor.

As shown in Table 1, the second transistor T2 and the third transistor T3 may have similar driving characteristics. It can be seen that even though the (2-2)-th gate electrode G2-2 and the (3-2)-th gate electrode G3-2 are located on different layers, there is no significant difference in the driving characteristics of the second transistor T2 and the third transistor T3.

According to some embodiments of the present disclosure, the (2-2)-th electrode G2-2 may be located on a layer above the (3-2)-th gate electrode G3-2. Accordingly, the distance between the (2-2)-th electrode G2-2 and the second semiconductor layers S2, A2, and D2 may be shorter than the distance between the (3-2)-th gate electrode G3-2 and the third semiconductor layers S3, A3, and D3.

In this case, as shown in Table 1, the electron mobility (Mobility) and the current (lon) of the second transistor T2 may become greater. The write operation according to the second transistor T2 may be more important than the compensation operation according to the third transistor T3. Accordingly, the (2-2)-th electrode G2-2 is located closer to the second semiconductor layers S2, A2, and D2, and thus the electron mobility (Mobility) and the current (Ion) of the second transistor T2 may be greater than those of the third transistor T3.

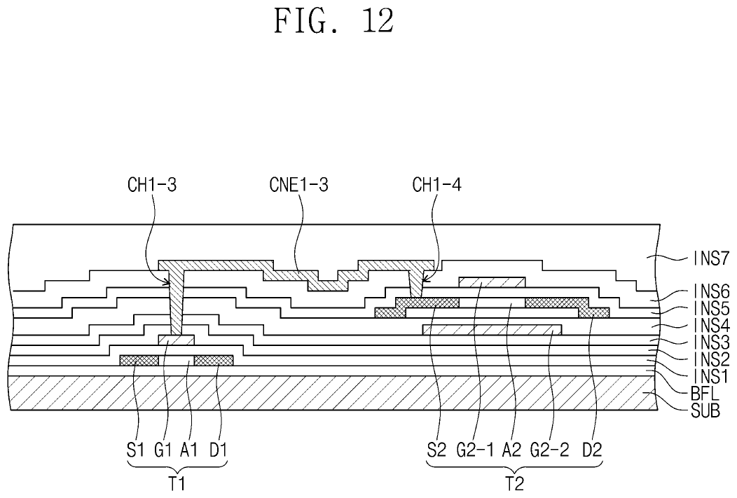

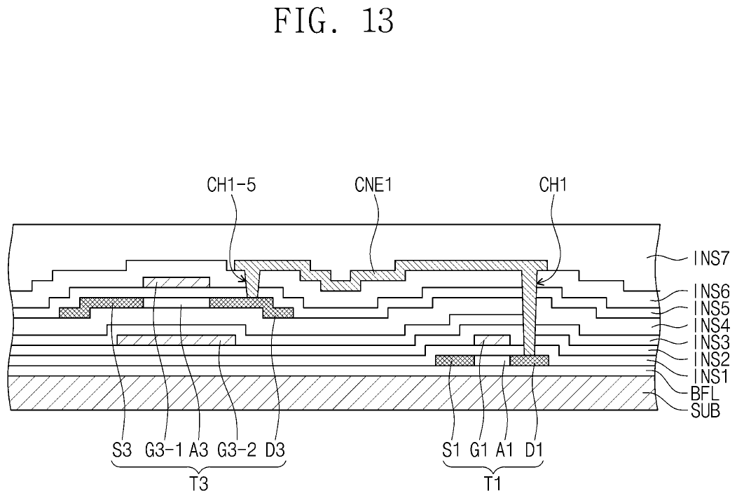

FIG. 12 is a cross-sectional view schematically illustrating a connection structure for a first transistor and a second transistor. FIG. 13 is a cross-sectional view schematically illustrating a connection structure for a first transistor and a third transistor.

For example, in FIGS. 12 and 13, cross sections of the eighth insulating layer INS8 and the light-emitting element OLED are omitted. For convenience of description, in FIG. 12, second semiconductor layers S2, A2, and D2 are illustrated, and third semiconductor layers S3, A3, and D3 extending to be continuous with the second semiconductor layers S2, A2, and D2 are omitted. Additionally, in FIG. 13, third semiconductor layers S3, A3, and D3 are illustrated, and second semiconductor layers S2, A2, and D2 extending to be continuous with the third semiconductor layers S3, A3, and D3 are omitted. Also, in FIGS. 12 and 13, the dummy electrode DME is omitted.

Referring to FIG. 12, a first connection electrode CNE1-3 may be located on a sixth insulating layer INS6. A first transistor T1 and a second transistor T2 may be connected via the first connection electrode CNE1-3.

The first connection electrode CNE1-3 may be connected to a first gate electrode G1 of the first transistor T1 via a first contact hole CH1-3 defined in second to sixth insulating layers INS2 to INS6. The first connection electrode CNE1-3 may be connected to a second source region S2 of the second transistor T2 via a first contact hole CH1-4 defined in the fifth and sixth insulating layers INS5 and INS6. Because the first gate electrode G1 defines the first node N1, the second source region S2 of the second transistor T2 may be connected to the first node N1.

Referring to FIG. 13, a first connection electrode CNE1 may be located on the sixth insulating layer INS6. A first transistor T1 may be connected to a third transistor T3 via the first connection electrode CNE1. The first connection electrode CNE1 may be the first connection electrode CNE1 illustrated in FIG. 9.

The first connection electrode CNE1 may extend, on the sixth insulating layer INS6, toward the third transistor T3. The first connection electrode CNE1 may be connected to a third drain region D3 of the third transistor T3 via a first contact hole CH1-5 defined in the fifth and sixth insulating layers INS5 and INS6. As described in FIG. 9, the first connection electrode CNE1 may be connected to the light-emitting element OLED and the first transistor T1. According to this structure, the third transistor T3 may be connected to the light-emitting element OLED and the first transistor T1.

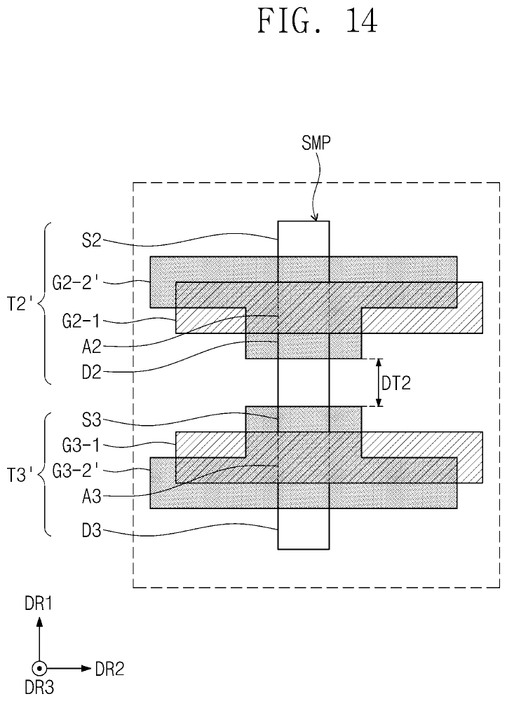

FIG. 14 is a view schematically illustrating a planar configuration of second and third transistors of a pixel according to Comparative Example.

For example, FIG. 14 is illustrated as a plan view corresponding to that of FIG. 10, and hereinafter, the description of a configuration illustrated in FIG. 14 will be mainly focused on components different from those illustrated in FIG. 10.

Referring to FIG. 14, a planar configuration of a second transistor T2′ and a third transistor T3′ may be the same as that of the second transistor T2 and the third transistor T3. However, a (2-2)-th gate electrode G2-2′ of the second transistor T2′ and a (3-2)-th gate electrode G3-2′ of the third transistor T3′ may be located on the same layer.

On the basis of the cross section illustrated in FIG. 11, the (2-2)-th gate electrode G2-2′ and the (3-2)-th gate electrode G3-2′ may be located on a second insulating layer INS2. However, embodiments according to the present disclosure are not limited thereto, and the (2-2)-th gate electrode G2-2′ and the (3-2)-th gate electrode G3-2′ may be located on a third insulating layer INS3.

When the (2-2)-th gate electrode G2-2′ and the (3-2)-th gate electrode G3-2′ are formed on the same layer, a process margin is required for preventing or relatively reducing defects such as a short circuit. For example, only when the (2-2)-th gate electrode G2-2′ is spaced apart from the (3-2)-th gate electrode G3-2′ by a certain distance or more, the (2-2)-th gate electrode G2-2′ and the (3-2)-th gate electrode G3-2′ may not be short-circuited.

For example, only when the (2-2)-th gate electrode G2-2′ is spaced apart from the (3-2)-th gate electrode G3-2′ by a second distance DT2, the (2-2)-th gate electrode G2-2′ and the (3-2)-th gate electrode G3-2′ may not be short-circuited. However, the second distance DT2 may be greater than the first distance DT1. When the (2-2)-th gate electrode G2-2′ is spaced apart from the (3-2)-th gate electrode G3-2′ by a distance greater than the second distance DT, the sizes of the pixels PX may become greater. When the sizes of the pixels PX increase, the number of the pixels PX which may be located in the display region DA may decrease.

Referring to FIGS. 10 and 11, according to some embodiments of the present disclosure, the (2-2)-th gate electrode G2-2 and the (3-2)-th gate electrode G3-2 may be located on the different layers, and may be insulated by the third insulating layer INS3. Accordingly, because the (2-2)-th gate electrode G2-2 and the (3-2)-th gate electrode G3-2 are unlikely to be short-circuited, the (2-2)-th gate electrode G2-2 and the (3-2)-th gate electrode G3-2 may be located further closer to each other by the first distance DT1.

The (2-2)-th gate electrode G2-2 and the (3-2)-th gate electrode G3-2 are located closer to each other, and thus the sizes of the pixels PX may become smaller. When the sizes of the pixels PX decrease, the number of pixels PX which may be located in the display region DA may increase. Therefore, according to some embodiments of the present disclosure, the high-resolution display device DD may be achieved.

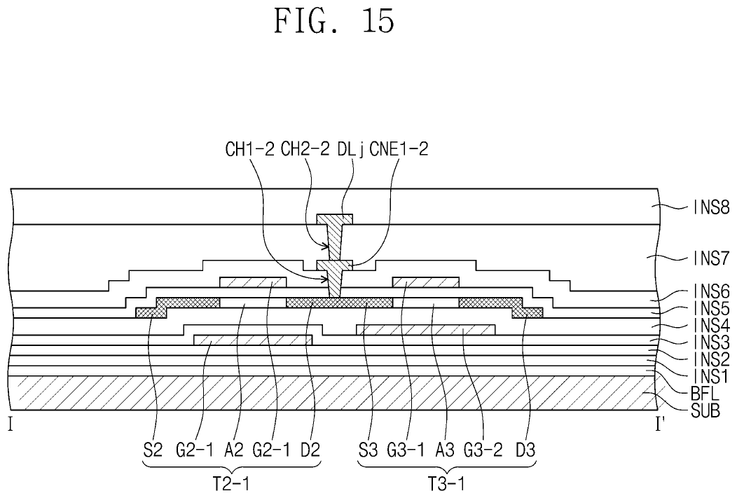

FIGS. 15 to 18 are views schematically illustrating cross-sectional configurations of second and third transistors according to some embodiments of the present disclosure.

For example, FIGS. 15 to 18 illustrate cross sections corresponding to that of FIG. 11, and hereinafter, the description of configurations illustrated in FIGS. 15 to 18 will be focused on components different from those illustrated in FIG. 11.

Referring to FIG. 15, a (2-1)-th transistor T2-1 may include second semiconductor layers S2, A2, and D2, a (2-1)-th gate electrode G2-1 located on the second semiconductor layers S2, A2, and D2, and a (2-2)-th gate electrode G2-2 located below the second semiconductor layers S2, A2, and D2. A (3-1)-th transistor T3-1 may include third semiconductor layers S3, A3, and D3, a (3-1)-th gate electrode G3-1 located on the third semiconductor layers S3, A3, and D3, and a (3-2)-th gate electrode G3-2 located below the third semiconductor layers S3, A3, and D3.

The (2-2)-th gate electrode G2-2 may be located on a second insulating layer INS2, and the (3-2)-th gate electrode G3-2 may be located on a third insulating layer INS3. Unlike what is illustrated in FIG. 11, the (3-2)-th gate electrode G3-2 may be located on a layer above the (2-2)-th gate electrode G2-2.

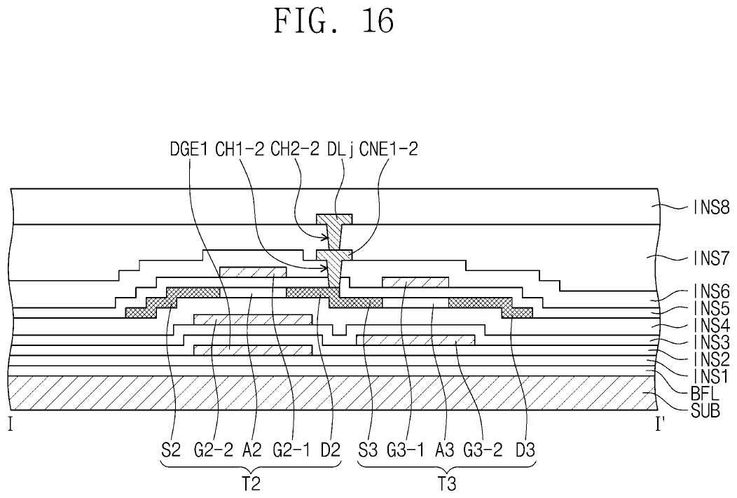

Referring to FIG. 16, second and third transistors T2 and T3 may have the same (or substantially the same) configuration as that of the second and third transistors T2 and T3 illustrated in FIG. 11. However, a first dummy gate electrode DGE1 may be located below a (2-2)-th gate electrode G2-2.

The first dummy gate electrode DGE1 may be located on the same layer as that of the first gate electrode G1 of the first transistor T1. For example, the first dummy gate electrode DGE1 may be located on a first insulating layer INS1, and a second insulating layer INS2 may be located on the first dummy gate electrode DGE1.

In a plan view, the first dummy gate electrode DGE1 may have an area greater than that of a second channel region A2, be located below the second channel region A2, and cover the second channel region A2. The first dummy gate electrode DGE1 may block, together with the (2-2)-th gate electrode G2-2, light provided from below a substrate SUB toward the second channel region A2.

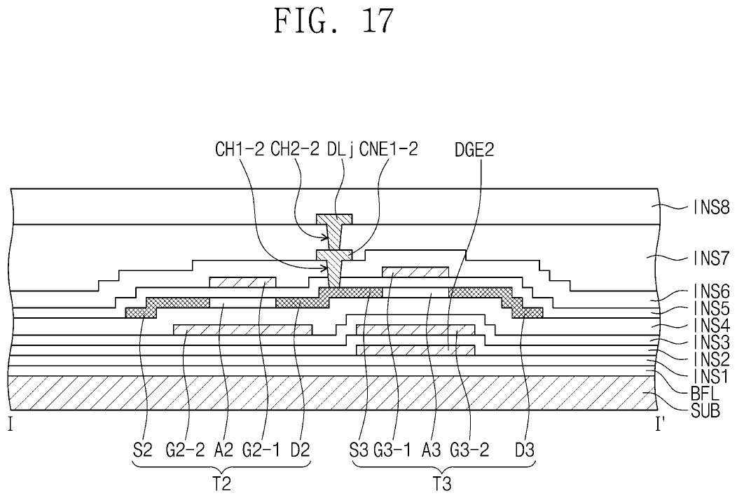

Referring to FIG. 17, second and third transistors T2 and T3 may have the same (or substantially the same) configuration as that of the second and third transistors T2 and T3 illustrated in FIG. 11. However, a second dummy gate electrode DGE2 may be located below a (3-2)-th gate electrode G3-2.

The second dummy gate electrode DGE2 may be located on the same layer as that of the first gate electrode G1 of the first transistor T1 described above. The second dummy gate electrode DGE2 may be located on a first insulating layer INS1, and a second insulating layer INS2 may be located on the second dummy gate electrode DGE2.

In a plan view, the second dummy gate electrode DGE2 may have an area greater than that of a third channel region A3, be located below the third channel region A3, and cover the third channel region A3. The second dummy gate electrode DGE2 may block, together with the (3-2)-th gate electrode G3-2, light provided from below a substrate SUB toward the third channel region A3.

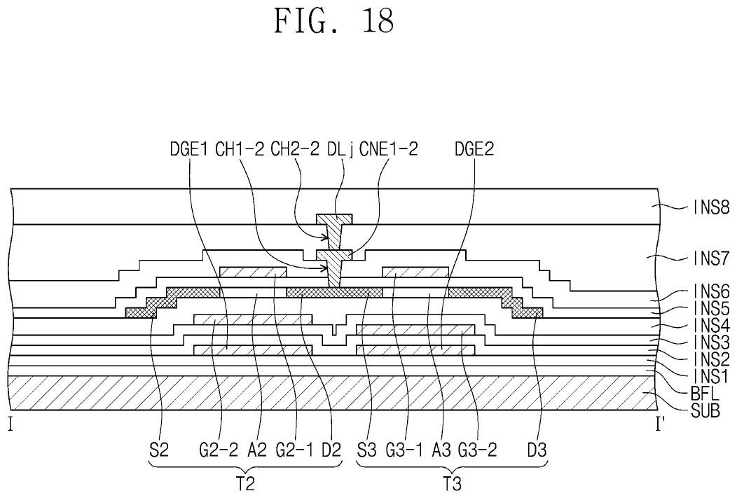

Referring to FIG. 18, second and third transistors T2 and T3 may have the same (or substantially the same) configuration as that of the second and third transistors T2 and T3 illustrated in FIG. 11. A first dummy gate electrode DGE1 may be located below a (2-2)-th gate electrode G2-2. A second dummy gate electrode DGE2 may be located below a (3-2)-th gate electrode G3-2.

The first dummy gate electrode DGE1 may block, together with the (2-2)-th gate electrode G2-2, light provided from below a substrate SUB toward the second channel region A2. The second dummy gate electrode DGE2 may block, together with the (3-2)-th gate electrode G3-2, light provided from below a substrate SUB toward the third channel region A3.

According to some embodiments of the present disclosure, an interval between a second pixel and a third pixel in each pixel may be relatively reduced, thereby relatively reducing the sizes of respective pixels. Accordingly, the number of pixels which may be located in a display region may be relatively increased, thereby achieving a high-resolution display device.

In the above, description has been made with reference to some embodiments of the present disclosure, but those skilled in the art or those of ordinary skill in the relevant technical field may understand that various modifications and changes may be made to the disclosed embodiments of the present disclosure without departing from the spirit and scope of embodiments according to the present disclosure described in the claims to be described later. In addition, the embodiments disclosed in the present disclosure are not intended to limit the technical spirit of embodiments according to the present disclosure, and all technical ideas within the scope of the following claims and their equivalents should be construed as being included in the scope of embodiments according to the present disclosure.

What is claimed is:

1. A display device comprising:
a light-emitting element;
a first transistor including a first semiconductor layer connected to a first power supply line and the light-emitting element, and a first gate electrode on the first semiconductor layer and connected to a first node;
a second transistor including a second semiconductor layer connected to the first node and a second node, a (2-1)-th gate electrode on the second semiconductor layer, and a (2-2)-th gate electrode below the second semiconductor layer;
a data line connected to the second node; and
a third transistor including a third semiconductor layer connected to the second node and the light-emitting element, a (3-1)-th gate electrode on the third semiconductor layer, and a (3-2)-th gate electrode below the third semiconductor layer,
wherein the (2-2)-th gate electrode and the (3-2)-th gate electrode are on layers above the first gate electrode, and are on different layers.

2. The display device of claim 1, further comprising an insulating layer on the first transistor,
wherein the (2-2)-th gate electrode and the (3-2)-th gate electrode are on the insulating layer.

3. The display device of claim 2, wherein the (2-2)-th gate electrode is on a layer above the (3-2)-th gate electrode.

4. The display device of claim 2, wherein the (3-2)-th gate electrode is on a layer above the (2-2)-th gate electrode.

5. The display device of claim 1, wherein the first semiconductor layer comprises polysilicon.

6. The display device of claim 5, wherein the second semiconductor layer and the third semiconductor layer each comprise an oxide semiconductor.

7. The display device of claim 1, wherein the first semiconductor layer comprises:
a first source region connected to a first power supply line;
a first drain region connected to the light-emitting element; and
a first channel region between the first source region and the first drain region, and
in a plan view, the first gate electrode overlaps the first channel region.

8. The display device of claim 1, wherein the second semiconductor layer comprises:
a second source region connected to the first node;
a second drain region connected to the second node; and
a second channel region between the second source region and the second drain region, and
in a plan view, the (2-1)-th gate electrode overlaps the second channel region.

9. The display device of claim 8, wherein the (2-2)-th gate electrode has an area greater than that of the second channel region in the plan view, is below the second channel region, and covers the second channel region.

10. The display device of claim 8, further comprising a first dummy gate electrode below the (2-2)-th gate electrode.

11. The display device of claim 10, wherein the first dummy gate electrode is on a same layer as the first gate electrode.

12. The display device of claim 10, wherein the first dummy gate electrode has an area greater than that of the second channel region in the plan view, is below the second channel region, and covers the second channel region.

13. The display device of claim 1, wherein the third semiconductor layer comprises:
a third source region connected to the second node;
a third drain region connected to the light-emitting element; and
a third channel region between the third source region and the third drain region, and
in a plan view, the (3-1)-th gate electrode overlaps the third channel region.

14. The display device of claim 13, wherein the (3-2)-th gate electrode has an area greater than that of the third channel region in the plan view, is below the third channel region, and covers the third channel region.

15. The display device of claim 13, further comprising a second dummy gate electrode below the (3-2)-th gate electrode.

16. The display device of claim 15, wherein the second dummy gate electrode is on a same layer as the first gate electrode.

17. The display device of claim 16, wherein the second dummy gate electrode has an area greater than that of the third channel region in the plan view, is below the third channel region, and covers the third channel region.

18. A display device comprising:
a light-emitting element;
a first transistor including a first semiconductor layer connected to a first power supply line and the light-emitting element, and a first gate electrode on the first semiconductor layer and connected to a first node;
a second transistor including a second semiconductor layer connected to the first node and a second node, a (2-1)-th gate electrode on the second semiconductor layer, and a (2-2)-th gate electrode below the second semiconductor layer;
a data line connected to the second node; and
a third transistor including a third semiconductor layer connected to the second node and the light-emitting element, a (3-1)-th gate electrode on the third semiconductor layer, and a (3-2)-th gate electrode below the third semiconductor layer,
wherein the (2-2)-th gate electrode and the (3-2)-th gate electrode are on layers above the first gate electrode, and the (2-2)-th gate electrode is on a layer above the (3-2)-th gate electrode.

19. The display device of claim 18, further comprising:
a first dummy gate electrode below the (2-2)-th gate electrode; and
a second dummy gate electrode below the (3-2)-th gate electrode.

20. A display device comprising:
a light-emitting element;
a first transistor including a first semiconductor layer connected to a first power supply line and the light-emitting element, and a first gate electrode on the first semiconductor layer and connected to a first node;
an insulating layer on the first transistor;
a second transistor including a second semiconductor layer on the insulating layer and connected to the first node and a second node, a (2-1)-th gate electrode on the second semiconductor layer, and a (2-2)-th gate electrode below the second semiconductor layer;
a data line connected to the second node; and
a third transistor including a third semiconductor layer on the insulating layer and connected to the second node and the light-emitting element, a (3-1)-th gate electrode on the third semiconductor layer, and a (3-2)-th gate electrode below the third semiconductor layer,
wherein the (2-2)-th gate electrode and the (3-2)-th gate electrode are on different layers on the insulating layer.
